(19) United States
(12) Patent Application Publication
(10) Pub. No.: US 2022/0328651 A1
(43) Pub. Date: Oct. 13, 2022

(54) Semiconducting Ferroelectric Device with Silicon Doped Electrode

(71) Applicant: Cerfe Labs, Inc., Austin, TX (US)

(72) Inventors: Saurabh Vinayak Suryavanshi, Mountain View, CA (US); Lucian Shifren, San Jose, CA (US); Carlos A. Paz de Araujo, Colorado Springs, CO (US); Jolanta B. Celinska, Colorado Springs, CO (US)

(21) Appl. No.: 17/715,716

(22) Filed: Apr. 7, 2022

Related U.S. Application Data
(60) Provisional application No. 63/172,948, filed on Apr. 9, 2021.
(60) Provisional application No. 63/172,957, filed on Apr. 9, 2021.
(60) Provisional application No. 63/172,964, filed on Apr. 9, 2021.

(51) Int. Cl. H01L 29/51; H01L 21/28; H01L 29/49; H01L 27/1159; H01L 29/66; H01L 29/78

(52) U.S. Cl. CPC H01L 29/516; H01L 29/40111; H01L 29/4966; H01L 27/1159; H01L 29/6684; H01L 29/78391; H01L 29/4916

(57) ABSTRACT

A device stack for an electronic memory or other device includes a substrate and first and second layers of insulating material. The first layer of insulating material is supported by the substrate. A semiconducting ferroelectric layer is positioned and electrically isolated between the first and second layers of insulating material. A stress layer capable of converting a ferroelectric or semiconductor material into a semiconducting ferroelectric material can be positioned in contact with the semiconducting ferroelectric layer. In some embodiments, the device is a Metal-Insulator-FeS-Insulator-Semiconductor (MIFIS) device that allows for controlled switching of the semiconducting ferroelectric (FeS) layer between various polarization states. Switching polarization states is enabled by application of an electric field by a semiconducting electrode.

### RELATED APPLICATION

The present disclosure is part of a non-provisional patent application claiming the priority benefit of U.S. Patent Application No. 63/172,948, filed on Apr. 9, 2021; U.S. Patent Application No. 63/172,957, filed on Apr. 9, 2021; U.S. Patent Application No. 63/172,964, filed on Apr. 9, 2021; all of which are hereby incorporated by reference in their entirety.

### FIELD OF THE INVENTION

A semiconducting ferroelectric device able to be manufactured and including a silicon doped electrode capable of applying an electric field to a semiconducting ferroelectric material is described. In some embodiments, the device allows for controlled switching of a ferroelectric layer between various polarization states.

### BACKGROUND

Ferroelectric insulator materials that exhibit polarization are available. Such polarization can be reoriented by ion displacement in the crystal into two or more nonvolatile states that can be controllably switched between using an external electric field. Unfortunately, such devices can have short polarization state retention time, in part because charge accumulation at the ferroelectric insulator and semiconductor interface lead to threshold voltage drift.

To improve device performance, composition and structure can be arranged so that ferroelectric materials can be encourages to cleanly switch between polarization states. Similarly, composition and structure can be arranged to improve ease of reading polarization state.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1A is a schematic representation of a semiconducting ferroelectric device;

FIG. 1B is a schematic representation of a semiconducting ferroelectric device with interface buffer layers between a semiconducting ferroelectric layer and insulator layers;

FIG. 1C is a schematic representation of a semiconducting ferroelectric device with interface buffer layers between a multilayer semiconducting ferroelectric layer and multilayer insulator layers;

FIG. 1D is a schematic representation of a semiconducting ferroelectric device with one or more conductive layers positioned between a multilayer semiconducting ferroelectric layer and multilayer insulator layers;

FIG. 1E is a schematic representation of a semiconducting ferroelectric device with one or more stress layers positioned between a multilayer semiconducting ferroelectric layer and multilayer insulator layers;

FIG. 1F is a schematic representation of a semiconducting ferroelectric device with a doped silicon or other semiconductor electrode;

FIG. 2 is a schematic representation of a process for manufacture of an improved semiconducting ferroelectric device; and

FIG. 3 illustrates a plurality of devices connected to at least one controller able to force polarization state changes in devices and allow for read of device state.

### DETAILED DESCRIPTION

Reference will now be made in detail to the described embodiments, examples of which are illustrated in the accompanying drawings. To the extent possible, in the Figures similar structures will be identified using similar reference characters. It will be understood that the Figures are presented for the purpose of describing particular embodiments of the invention and are not intended to limit the invention thereto.

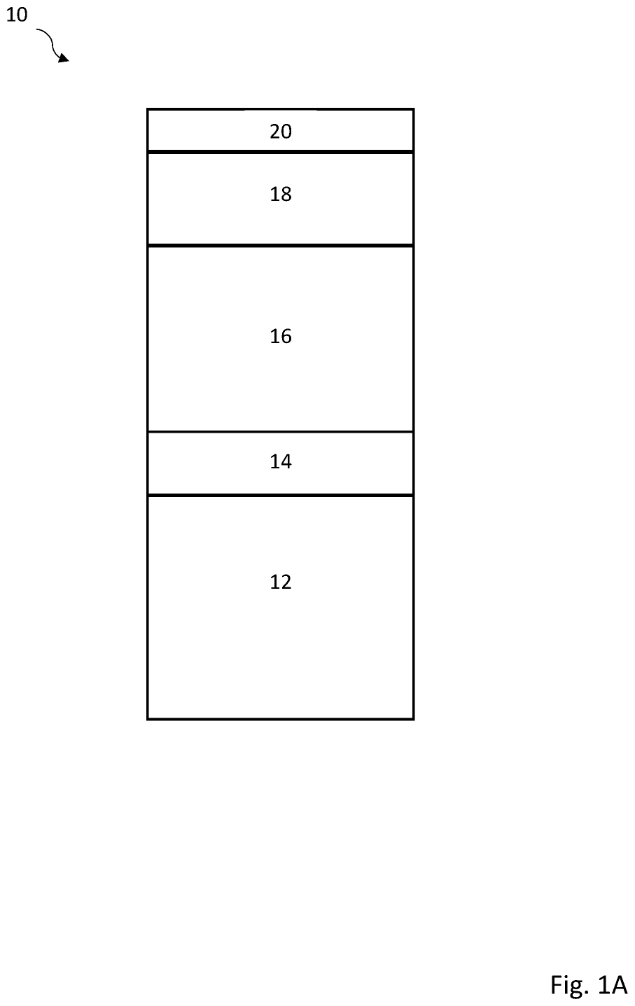

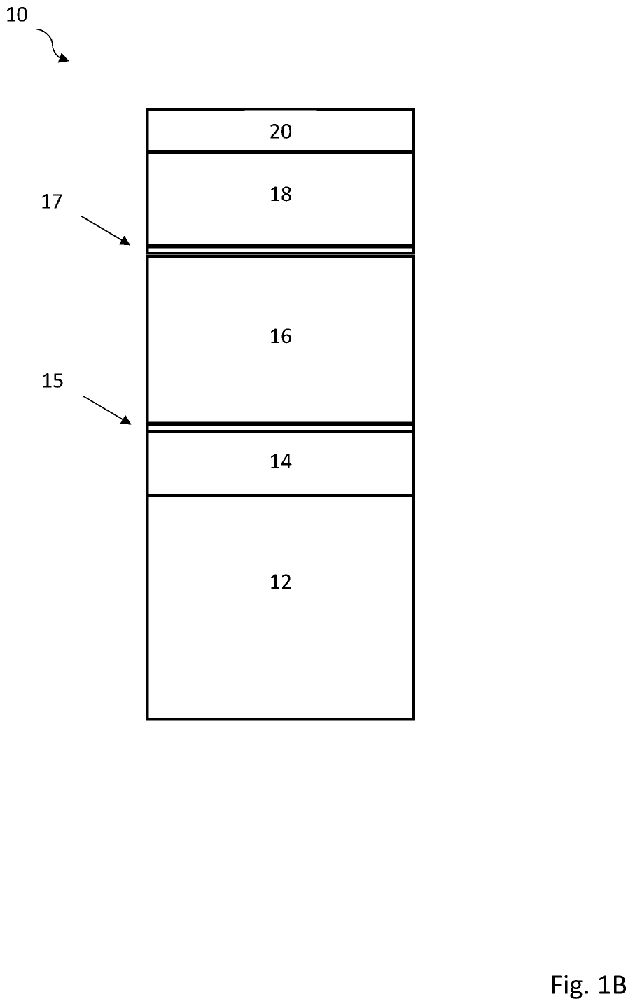

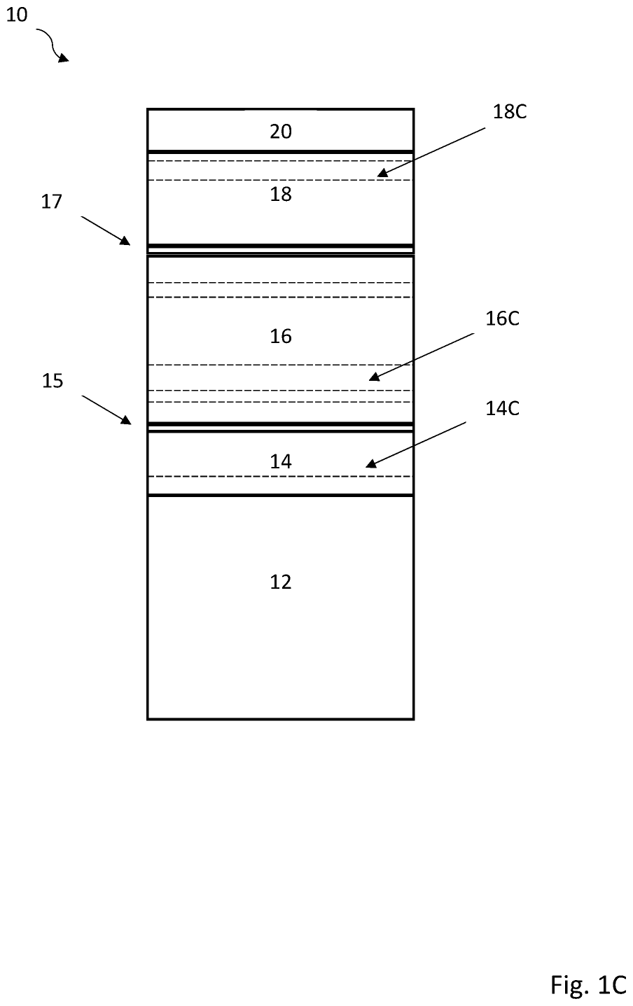

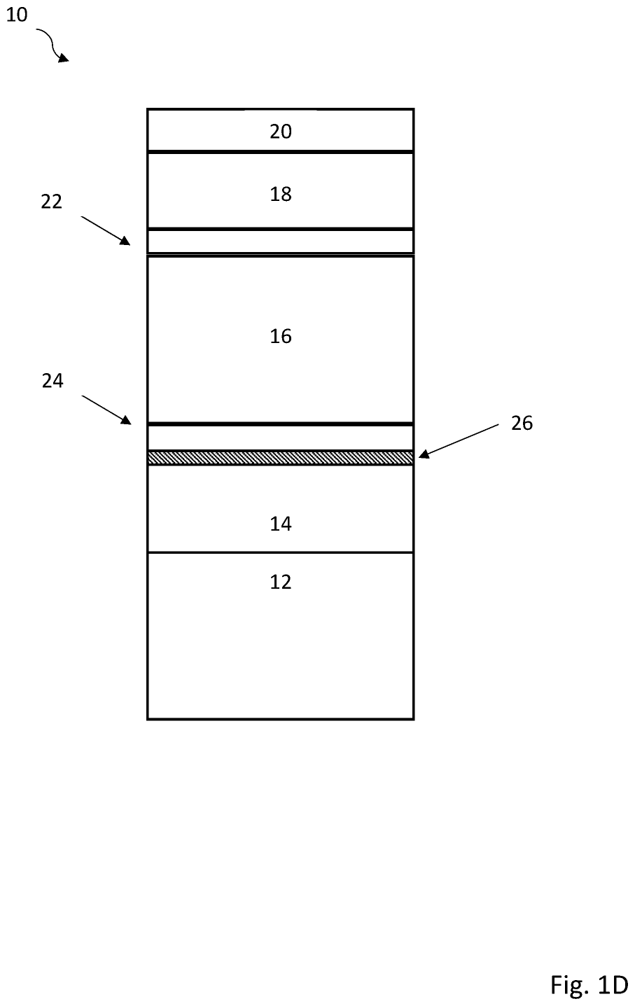

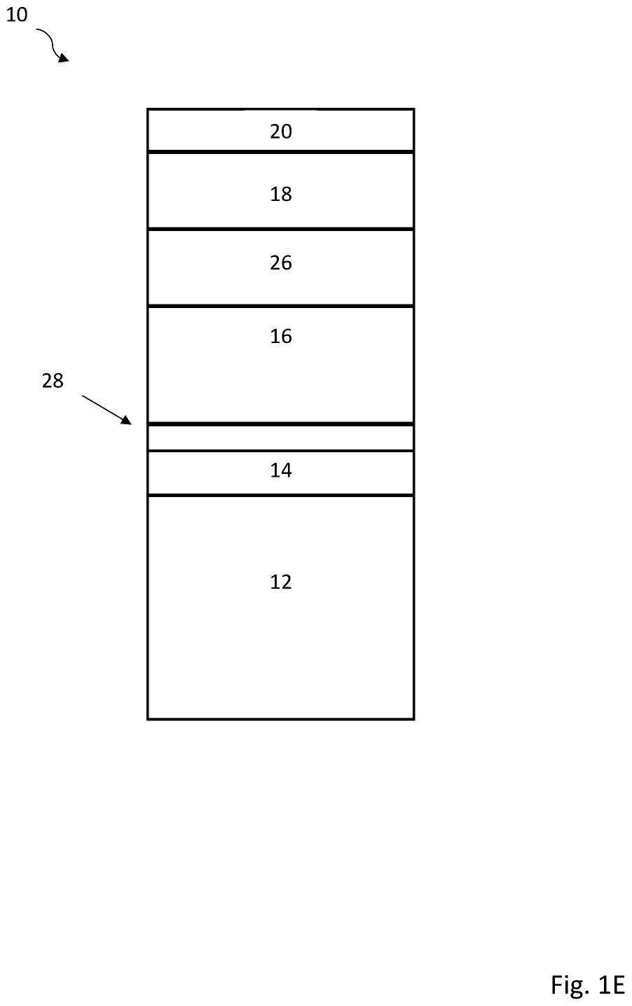

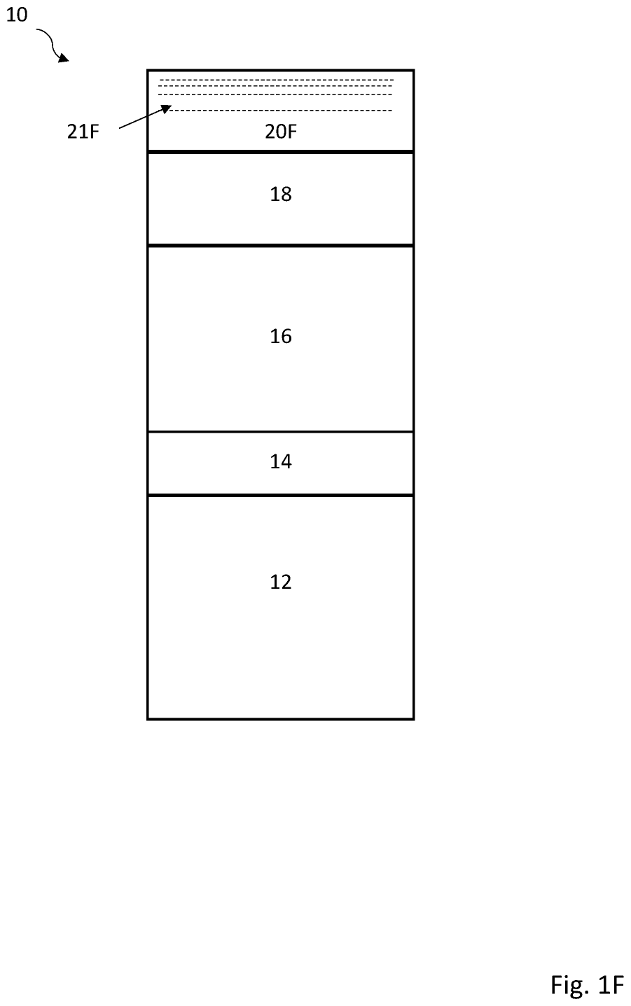

FIG. 1A shows a schematic representation of an embodiment of semiconducting ferroelectric device stack 10. The semiconducting ferroelectric device stack 10 includes a substrate 12 having a formed or deposited first insulator layer 14. A semiconducting ferroelectric layer 16 having spontaneous or induced polarization is situated on or above the first insulator layer 14. A second insulator layer 18 is situated on or above the semiconducting ferroelectric layer 16. An electrode 20 can be deposited on or above the second insulator layer 18. In one embodiment, the semiconducting ferroelectric layer 16 is electrically isolated from the substrate 12 and the electrode 20 due to its position between first insulator layer 14 and second insulator layer 18. In some embodiments the substrate 12 can be formed in whole or in part from semiconducting material.

FIG. 1B is similar to device stack 10 of FIG. 1A, but further illustrates two buffer layers 15 and 17 positioned respectively between the insulator layers 14 and 18, and the semiconducting ferroelectric layer 16. The material of the buffer layers 15 and 17 can be selected to improve layer adhesion, provide lattice matching, or allow for deposition of disparate material. In some embodiments, the buffer layers 15 and 17 can be used to modify electrical properties. In some embodiments the buffer layers 15 and 17 can be insulators. For example, in one embodiment buffer layer 15 can be formed from 0.1 to 4 nm thick, while buffer layer 17 can be formed from 0.1 to 4 nm thick. Buffer layers 15 and 17 can be respectively formed during deposition, by thermal or laser processing, or through ion implantation. In some embodiments metal organic chemical vapor deposition, atomic layer deposition, pulse laser deposition, sputtering, or the other techniques can be used to form multilayers within the insulator or semiconducting ferroelectric layers.

FIG. 1C is similar to device stack 10 of FIGS. 1A and 1B, but illustrates use of compositionally, dopant, or crystal structure distinct multilayers 14C, 18C, and 16C for respective insulator layers 14 and 18, and the semiconducting ferroelectric layer 16. Such multilayers can improve deposition, material, or electrical characteristics, and can be formed during deposition, thermal or laser processing, or through ion implantation. In some embodiments metal organic chemical vapor deposition, atomic layer deposition, pulse laser deposition, sputtering, or the other techniques can be used to form multilayers within the insulator or semiconducting ferroelectric layers.

1D is similar to device stack 10 of FIG. 1A, but further illustrates two conductive layers 22 and 24 positioned respectively between the insulator layers 14 and 18, and the semiconducting ferroelectric layer 16. In some embodiments, either conductive layer 22 or 24 can be omitted, to provide a single conductive layer. In still other embodiments, multiple conductive layers of one or more materials can be deposited or formed. In effect, having a conductive layer positioned at least one of below and above the semiconducting ferroelectric layer can improve device operation. For example, the conductive layers 22 and 24 can act to reduce issues with flux pinning or electron distribution that can interfere with polarization switching or read of the semiconducting ferroelectric layer 16.

In some embodiments, material of the conductive layers 22 and 24 can be selected to improve layer adhesion, provide lattice matching, or allow for deposition of disparate material. In one embodiment conductive layers 22 and 24 can respectively be formed from 0.1 to 100 nm thick. Conductive layers 22 and 24 can be respectively formed during deposition, by thermal or laser processing, or through ion implantation. In some embodiments metal organic chemical vapor deposition, atomic layer deposition, pulse laser deposition, sputtering, or the other techniques can be used to form multilayers within conductive layers 22 and 24.

In some embodiments, conductive layers 22 and 24 can be respectively separated from the semiconducting ferroelectric layer 16 by conductive or semiconductive buffer layers. In some embodiments, the buffer layers can be used to modify electrical properties of the conductive layers 22 and 24 or semiconducting ferroelectric layer 16, as well as improving layer adhesion, provide lattice matching, or allowing for deposition of disparate materials. In some embodiments buffer layers can be formed from 0.1 to 4 nm thick. Buffer layers can be respectively formed during deposition, by thermal or laser processing, or through ion implantation. In some embodiments metal organic chemical vapor deposition, atomic layer deposition, pulse laser deposition, sputtering, or the other techniques can be used to form multilayers within the insulator or semiconducting ferroelectric layers.

The conductive layers 22 or 24 can be formed from various materials, including metals, metalloids, non-dielectric or a conductive oxides. Metalloids can include metals or metallic compounds such as boron, silicon, germanium, arsenic, antimony, and tellurium that have intermediate properties between metals and non-metals. In those embodiments where a non-dielectric or conductive oxide is used, suitable conductivity can be assured by providing a doped conductive oxide, a conductive metal oxide, a doped conductive metal oxide, a semiconductive oxide, or a semiconductive metal oxide. In some embodiments the conductive layer comprises a conductive perovskite oxide, a high temperature superconducting oxide, or an oxide film of any metal selected from a group consisted of Mo, W, Tc, Re, Ru, Os, Rh, Ir, Pd, Pt, In, Zn, Sn, Nd, Nb, Sm, La, and V. In other embodiments the conductive layer includes a conductive oxide that comprises at least one of indium oxide, indium tin oxide, ruthenium oxide, iridium oxide, tungsten oxide, molybdenum oxide, titanium oxide, iron oxide, tin oxide, zinc oxide, CeO2, Ga2O3, SrTiO3, LaFeO3, or CrxTiyO3. In still other embodiments, conductive layers 22 or 24 can be formed from oxides with metals from Group 3 (VI) lanthanides, Group 4 (V) transition metals, Group 5 (IV) transition metals, Group 6 (IV) transition metals, Group 6 (VI) transition metals, Group 7 (IV) transition metals, Group 8 (IV) transition metals, Group 8 (V) transition metals, Group 9 (IV) transition metals, Group 10 (IV) transition metals, Group 11 (IV) transition metals, Group 12 (IV) transition metals, Group 12 (V) transition metals, Group 13 (IV) transition metals, Group 13 (V) transition metals, Group 14 (IV) transition metals, singly, alloyed, or in combination. Examples include but are not limited to VO₂, TiO₂, Cr₂O₃, WO₃, MnO, Mn₃O₄, MnO₂, FeO, Fe₃O₄, Fe₂O₃, Fe₃O₄, RuO₂, CoO, Co₃O₄, Fe₃O₄, NiO, CuO, Cu₂O, ZnO, CdO, or Ga₂O₃.

In still other embodiments, conductive layers can be formed from conductive oxide that can include any number of conductive perovskite oxides such as lanthanum strontium cobalt oxide (LSCO). Typical examples of simple perovskite oxides are expressed by the general formula ABO₃ such as SrRuO₃ or LaNiO₃, where AB can be any combination of (A=Ca, Sr)(B=V, Cr, Fe, Ru), (A=La)(B=Ti, Co, Ni, Cu), (A=H, Li, Na, K)(B=Re, Mo, Nb), (A=La1−xSrx)(B=V, Mn, Co). Another example of conductive perovskite oxides is expressed by the general formula A₂B₂O₇ where (A=Bi, Pd)(B=Ru₁₋ₓBiₓ, Ru₁₋ₓPbₓ). Examples of layered perovskite oxides include CaTiO, (Sr(Ru, Ir, Cr)O₃)(SrO)n such as SrRuO₃, SrIrO₃, Sr₂RuO₄, Sr₂IrO₄ and Ba₂RuO₄. The conductive oxide film can also include high temperature superconducting oxides such as La₁₋ₓ SrₓCuO₄, Nd₁₋ₓ CeₓCuO₄, YBa₂Cu₃O₇, Bi₂Sr₂Caₙ₋₁ CuₙO₂ₙ₊₄, (Nd₁₋ₓCex)₂CuO₄.

Adjustments or modification to physical and electrical properties of conductive layers 22 or 24 can be made during or after deposition. For example, metals or metalloids can have properties adjusted by alloying or crystal size modification. Conductive oxides can be modified by introduction of substituent or modifier atoms that act to adjust various material and electrical properties by replacement of some relatively small number of cation sites with other types of cations. Conductive oxides can also be changed by introduction of small amounts of dopant atoms that act to adjust various material and electrical properties. In some embodiments, small amounts of insulator material can be introduced to modify resistivity or other properties. This can include an element or its non-conductive oxide such as hafnium or hafnium oxide (HfO₂ and its variants of oxygen-rich or oxygen-deficiency HfOₓ), zirconium or zirconium oxide (ZrO₂ and its variants of oxygen-rich or oxygen-deficiency ZrOₓ), lanthanum or lanthanum oxide (LaO₂ and its variants of oxygen-rich or oxygen-deficiency LaOₓ), or aluminum or aluminum oxide (Al₂O₃ and its variants of oxygen-rich or oxygen-deficiency AlOₓ). The conductive oxide can be In₂O₃ with the dopant species being hafnium, zirconium, lanthanum, aluminum or their oxides.

In some embodiments, an optional barrier layer 26 can be positioned between the conducting layer 24 and the insulator layer 14. The material for layer 26 can be selected to reduce defect pinning (allowing insulator 14 to be used as a floating gate) or provide other advantageous properties, including improving layer adhesion, providing lattice matching, or allowing for deposition of disparate materials. In some embodiments optional barrier layer 26 can be formed from 0.1 to 4 nm thick. Optional barrier layer 26 can be respectively formed during deposition, by thermal or laser processing, or through ion implantation. In some embodiments metal organic chemical vapor deposition, atomic layer deposition, pulse laser deposition, sputtering, or the other techniques can be used to form multiple distinct material layers to together constitute optional barrier layer 26.

FIG. 1E is similar to device stack 10 of FIG. 1A, but further illustrates two stress layers 26 and 28 positioned respectively between the insulator layers 14 and 18, and the semiconducting ferroelectric layer 16. In some embodiments, either stress layer 26 or 28 can be omitted, to provide a single stress layer. In still other embodiments, multiple stress layers of one or more materials can be deposited or formed. In one embodiment, a stress layer can strain a contacting, adjacent, or near positioned material layer sufficiently to convert it from a ferroelectric material into a semiconducting ferroelectric layer. In another embodiment, a stress layer can strain a contacting, adjacent, or near positioned material layer sufficiently to convert it from a semiconductor material into a semiconducting ferroelectric layer. In still other embodiments, compressive or tensile stress layers partially positioned laterally with respect to the material layer can be used. In some embodiments, internal stress layers caused by lattice mismatch can be used. Such internal stress can include uniaxial, biaxial, or triaxial stress. In other embodiments, external stress caused by stress layers that surround or contact surrounding insulator or other layers to provide tensile or compressive stresses can be used. In some embodiments, such external stress applying layers can laterally direct stress. Advantageously, use of stress layers can increase the range of materials suitable for forming semiconducting ferroelectric layers, decrease or increase acceptable material thickness ranges, reduce or eliminate need for substituents or dopants in the material, allow for reductions in concentration of substituents or dopants, or allow for improving polarization switching performance.

In some embodiments, material of the stress layers 26 and 28 can be selected to improve layer adhesion, increase lattice mismatch, or allow for deposition of disparate material. In one embodiment stress layers 26 and 28 can respectively be formed from 0.1 to 400 nm thick. Stress layers 26 and 28 can be respectively formed during deposition, by thermal or laser processing, or through ion implantation. In some embodiments, stress layers can be formed by be formed by any epitaxial growth process that ensures that the strained epitaxial semiconductor material has a substantially same crystallographic structure as that of the surface of the ferroelectric or semiconductor material. The epitaxial growth process can employ at least one precursor-containing gas such as SiH₄ (silane), SiH₂Cl₂ (dichlorosilane), SiHCl₃ (trichlorosilane), SiCl₄ (tetrachlorosilane), Si₂H₆ (disilane), Si₃H₈ (trisilane), GeH₄ (germane), and SiCH₆ (monomethylsilane). In some embodiments metal organic chemical vapor deposition, atomic layer deposition, pulse laser deposition, sputtering, or the other techniques can be used to form multilayers within stress layers 26 and 28.

In some embodiments, stress layers 26 and 28 can be respectively separated from the semiconducting ferroelectric layer 16 by conductive or semiconductive buffer layers. These can include conductive oxides. In some embodiments, the conductive or buffer layers can be used to modify electrical properties of the semiconducting ferroelectric layer 16, as well as improving layer adhesion, provide lattice matching (or mismatch), or allowing for deposition of disparate materials. In some embodiments buffer layers can be formed from 0.1 to 4 nm thick. Buffer layers can be respectively formed during deposition, by thermal or laser processing, or through ion implantation. In some embodiments metal organic chemical vapor deposition, atomic layer deposition, pulse laser deposition, sputtering, or the other techniques can be used to form multilayers within the insulator or semiconducting ferroelectric layers.

The stress layers 26 or 28 can be formed from various materials, including any monocrystalline material that can be grown in contact with the ferroelectric or semiconductive material with a different lattice constant. In effect, the difference in lattice constant of the juxtaposed materials generates a stress at the interface that is redistributed to the ferroelectric or semiconductive material. Preferably the stress inducing material causes the ferroelectric or semiconductive material to deform elastically so that the material is stressed but remains a substantially defect free perfect crystal. Stress layers can be formed from doped and/or undoped semiconductors, and can include a range of materials, including Group IV elemental semiconductors, (C, Si, Ge, Sn), Group IV compound semiconductors, Group VI elemental semiconductors, (S, Se, Te), III-V semiconductors, II-VI semiconductors, I-VII semiconductors, IV-VI semiconductors, V-VI semiconductors, II-V semiconductors, I-III-VI2 semiconductors, oxides, or layered semiconductors. In some embodiments, oxide or nitride ceramics such as silicon nitride can be used. In still other embodiments, carbon containing materials such as carbon doped silicon germanium (SiGe:C) or carbon doped silicon (Si:C) can be used.

Adjustments or modification to physical and electrical properties of stress layers 26 or 28 can be made during or after deposition. For example, stress layers can be modified by introduction of substituent or modifier atoms that act to adjust various material and electrical properties by replacement of some relatively small number of cation sites with other types of cations. Stress layers can also be changed by introduction of small amounts of dopant atoms, including but limited to bismuth, that act to adjust various crystallographic, material and electrical properties.

FIG. 1F is similar to device stack 10 of FIG. 1A, but further illustrates replacement or supplementation of a top metal electrode (e.g. electrode 20 of FIG. 1A) with a semiconductor 20F that can optionally be formed using dopant implants 20F. In one embodiment, the semiconductor that can be crystal silicon, crystal germanium, silicon carbide, doped and/or undoped semiconductors, and/or other semiconductor structures and/or technologies. In some embodiments, Group IV elemental semiconductors, (C, Si, Ge, Sn), Group IV compound semiconductors, Group VI elemental semiconductors, (S, Se, Te), III-V semiconductors, II-VI semiconductors, I-VII semiconductors, IV-VI semiconductors, V-VI semiconductors, II-V semiconductors, I-III-VI2 semiconductors, oxides, or layered semiconductors can be used. In some embodiments, conductive oxide or nitride ceramics such as silicon nitride can be used. In still other embodiments, carbon containing materials such as carbon doped silicon germanium (SiGe:C) or carbon doped silicon (Si:C) can be used.

Semiconductor 20F can be formed during deposition, by thermal or laser processing, or through ion implantation. In some embodiments metal organic chemical vapor deposition, atomic layer deposition, pulse laser deposition, sputtering, or the other techniques can be used to form multilayers within the semiconductor 20F. In some embodiments, metal or other conducting layers can be positioned below, within, or on top of the semiconductor 20F.

In some embodiments, electrode 20F can be biased or maintained at a positive, a negative, or zero bias. The electrode 20F can be additionally attached in electrical connection with various support circuitry, such as driver and/or decode circuitry, for example, associated with of one or more device stacks such as discussed herein.

In one embodiment of operation, semiconducting ferroelectric device stack 10 of FIG. 1A, 1B, 1C, 1D, or 1E is a Metal-Insulator-FeS-Insulator-Semiconductor (MIFIS) device that allows for controlled switching of the semiconducting ferroelectric (FeS) layer between various polarization states. Switching polarization states is enabled by application of an electric field by electrode 20. Additionally, identity of the polarization state is detectable using circuitry (not shown) connected to the electrode 20. In some embodiments, polarization state is retained indefinitely until it is actively switched using electrode 20, making the semiconducting ferroelectric device stack 10 suitable for use in non-volatile memory applications. As an example, the semiconducting ferroelectric device stack 10 can be a component of non-volatile flash memory device utilizing semiconducting ferroelectric layer 16 as a floating gate in a floating-gate field-effect metal oxide transistor. In some embodiments, electric fields below about 2 MV/cm can be used for changing polarization of the semiconducting ferroelectric layer 16. In other embodiments, electric fields below about 100 kV/cm can be used for changing polarization of the semiconducting ferroelectric layer 16. In still other embodiments, electric fields ranging between 100 kV/cm and 500 kV/cm can be used for changing polarization of the semiconducting ferroelectric layer 16. For ease of manufacturability in CMOS fabrication facilities, materials forming the semiconducting ferroelectric layer 16 can be annealed at temperatures less than 450 degrees C.

In some embodiments, the substrate 12 includes a semiconductor that can be crystal silicon, crystal germanium, silicon carbide, silicon-on-insulator (SOI) or silicon-on-sapphire (SOS) technology, doped and/or undoped semiconductors, epitaxial layers of silicon supported by a base semiconductor foundation, conventional metal oxide semiconductors (CMOS), and/or other semiconductor structures and/or technologies. In some embodiments, the substrate 12 can act as a semiconductive substrate. The substrate 12 can be biased or maintained at zero bias. The substrate can additionally support various circuitry, such as driver and/or decode circuitry, for example, associated with of one or more device stacks formed in and/or on substrate 12. Furthermore, when reference is made to a “substrate” in the following description, previous process steps may have been utilized to form regions and/or junctions in the base semiconductor structure or foundation.

In some embodiments, the first insulator layer 14 can include dielectrics such as deposited metal oxides or nitrides. Metal oxides or nitrides can include single, mixed, or layered oxides or nitrides. In some embodiments, hafnium, zirconium, lanthanum, yttrium, aluminum, magnesium and/or manganese oxides can be used. Alternatively or in addition aluminum nitride, hafnium nitride, and mixed nitride of aluminum and hafnium can be used. In some embodiments, a composition such as Hf₍₁₋ₓ₎ZrₓO₂, where 0≤x≤1 can be used.

The first insulator layer 14 can have thickness ranging from 0.1 to 10 nm, with exact thickness depending on device stack size and application. The first insulator layer 14 can be formed by metal organic chemical vapor deposition, atomic layer deposition, pulse laser deposition, sputtering, or the other techniques.

In some embodiments, the semiconducting ferroelectric layer 16, optionally formed with the used of stress layers, can include one or more layers of a polarizable ferroelectric semiconducting material and typically has a thickness ranging from 1 to 80 nm. In some embodiments, thickness of the semiconducting ferroelectric layer 16 is greater than thickness of either the first insulator layer 14 or the second insulator layer 18. Typically, application of an applied electric field between electrode 20 and substrate 12 (acting as a semiconductive electrode) of less than 2 MV/cm is sufficient to modify polarity of the ferroelectric semiconducting material. In certain embodiments, an applied electric field between electrode 20 and substrate 12 of less than 2 MV/cm can be accomplished using an applied voltage less than 3V.

In some embodiments the semiconducting ferroelectric layer 16 optionally formed with the used of stress layers, can be formed from inorganic polycrystalline, ceramic, or crystalline materials, as well as organic polymeric materials such as polyvinylidene fluoride. In one embodiment the semiconducting ferroelectric layer 16 includes a material based on a ferroelectric ceramic, thin or thick film ferroelectric, or single crystal structure ferroelectric. Ferroelectric ceramics can be formed by using one or more combinations of films of strontium, bismuth, tantalum and oxygen, films of calcium, strontium, bismuth, tantalum and oxygen, films of strontium, bismuth, tantalum, niobium and oxygen, films of calcium, strontium, bismuth, tantalum, niobium and oxygen, films of bismuth, titanium and oxygen, films of bismuth, tantalum, titanium and oxygen, or films of bismuth, neodymium, titanium and oxygen. Alternatively or in addition, chemical solution deposition, metalorganic chemical vapor deposition (MOCVD), sputtering, laser ablation, or atomic layer deposition can be used.

In some embodiments, the ferroelectric ceramic can include a ferroelectric oxide having a crystal structure isomorphous with perovskite (CaTiO₃). Perovskites can have the general formula ABO₃, where A and B are cations. A-site cations can include Na⁺, K⁺, Na⁺, Ba²⁺, Sr²⁺, Pb²⁺, Bi³⁺, and Ca²⁺, while B-site cations can include Nb⁺, Ta⁵⁺, Zr⁴⁺, Ti⁴⁺, Pb⁴⁺, Sc³⁺, and Fe³⁺. Examples of ferroelectric ceramic oxide perovskites can include but are not limited to BaTiO₃, PbTiO₃, NaNbO₃, KNbO₃, KTaO₃, BiScO₃, and BiScO₃. In some embodiments, cation substituents can be made, allowing ceramic solid solutions of, for example, BaTiO₃ with PbTiO₃ or BaTiO₃ with CaTiO₃. In addition to simple perovskites with a general ABO₃ composition, a ferroelectric ceramic can be formed from complex perovskites where A and B sites are occupied by ions of a different valency in a fixed molar ratio. Examples include but are not limited to PbMg_{1/3}Nb_{2/3}O₃ (PMN), PbSc_{1/2}Ta_{1/2}O₃, and Bi_{1/2}Na_{1/2}TiO₃.

Alternatively, ferroelectric oxides can include ilmenite ferroelectrics having a general ABO3 composition, but where the A cation is too small to fill the coordinated site of the perovskite structure. Ilmenite structure is made up of hexagonal close-packed layers of oxygen ions, and with the A and B ions occupying the octahedrally coordinated sites between the layers. Examples include but are not limited to LiNb2O3 or LiTa2O3. In some embodiments, other classes of ferroelectric oxide materials including tungsten bronze ferroelectrics, Aurivillius compounds, phosphate ferroelectrics, or oxygen tetrahedral ferroelectrics can also be used.

Ferroelectric ceramics or oxides can be modified by introduction of substituent or modifier atoms that act to adjust various material and electrical properties by replacement of some relatively small number of cation sites with other types of cations. For example, a standard wide band insulating ferroelectric such as PZT (PbZr₍₁₋ₓ₎Ti₍ₓ₎O₃) can have various ratios of Zr to Ti modify the ferroelectric and other properties of the material. In those cases of PZT modification, for example, care is taken not to allow the material to become a semiconducting ferroelectric for the reason that the ferroelectric properties can be severely deteriorated. In the case of the semiconducting layer 16, the semiconductor ferroelectric can be designed to achieve high polarization and yet remain semiconducting for the low temperature annealing below 450 C. In the case of materials that can be made semiconducting ferroelectric, for example, with Bi₂O₃ added in quantities between 1%-20% of Bi₄Ti₃O₁₂ or other Bismuth based Aurivillius ferroelectrics, a large increase in semiconducting properties can be tailored in such a way that the internal screening of the spontaneous or induced polarization by free carriers such as electrons and holes, can be controlled. In such cases the semiconducting ferroelectric layer 16 can also be enhanced in spontaneous polarization by the addition of polarization enhancement modifiers such as Bi, Nb, La, Ta, Zr, Dy, Sm, Cr, Sb, Fe, Si, Al, Pb, Hf, Ba, or Cd in quantities from 1% to 20%. Substitution or modification can occur along with, or after deposition of the semiconducting ferroelectric layer 16, and substitution levels in the semiconducting ferroelectric layer 16 can be uniform, increasing/decreasing, or have custom percentage levels at each atomic layer in the formed semiconducting ferroelectric layer 16

Ferroelectric ceramics or oxides can be changed in conductivity and influence the overall polarization due to screening by introduction of small amounts of dopant atoms that act to adjust various material and electrical properties. For example, the semiconducting ferroelectric layer 16 can be doped to have at most 1% of one of Bi, Dy, Sm, Sc, Cr, Sb, Fe, Si, Al, Ga, Ge, Hf, Ba or Y. Doping can occur along with or after deposition of the semiconducting ferroelectric layer 16, and dopant levels in the semiconducting ferroelectric layer 16 can be uniform, increasing/decreasing, or have custom doped levels at each atomic layer in the formed ferroelectric layer 16. For example, in some embodiments the semiconducting ferroelectric layer 16 can be highly doped with Nb for a first portion, doped with a combination of Nb and Ta in a second portion, and finally doped with lesser amounts of Nb in a third portion.

In some embodiments, a ferroelectric ceramic oxide can include a single layer of a bismuth based ceramic such as bismuth titanate doped with transition metals or rare earth dopants, such as Nb, La, Ta, Zr, Dy, Sm, Cr, CrSb, Fe, Si, Al, Pb, Hf, Ba, or Cd can be used. In some embodiments Bi₄Ti₃O₁₂ doped with less than 15% by atomic mass of BixO_{y}, where 1≤x≤2, and 1≤y≤3 (BiO or Bi₂O₃) can be used. Other embodiments include strontium bismuth tantalum oxide (SrBi₂Ta₂O₉) material, a strontium bismuth tantalum niobium oxide (SrBi₂[Ta₍₁₋ₓ₎,Nbₓ]₂O₉, where 0<x<1) material, a bismuth lanthanum titanium oxide ([Bi, La]₄Ti₃O₁₂) material, or the like. In other embodiments, semiconducting ferroelectric layer 16 can be formed from multiple layers that include but are not limited to bismuth based ceramics.

In some embodiments, the second insulator layer 18 can include dielectrics such as deposited metal oxides or nitrides. Metal oxides or nitrides can include single, mixed, or layered oxides or nitrides. In some embodiments, hafnium, zirconium, lanthanum, yttrium, aluminum, magnesium and/or manganese oxides can be used. Alternatively or in addition aluminum nitride, hafnium nitride, and mixed nitride of aluminum and hafnium can be used. In some embodiments, a composition such as Hf₍₁₋ₓ₎Zr₍ₓ₎O₂, where 0≤x≤1 can be used.

The second insulator layer 18 can have thickness ranging from 0.5 to 10 nm, with exact thickness depending on device stack size and application. The second insulator layer 18 can be formed by metal organic chemical vapor deposition, atomic layer deposition, pulse laser deposition, sputtering, or the other techniques. In some embodiments, composition or thickness of the second insulator layer 18 can be the same or similar to that of first insulator layer 14.

In some embodiments, the electrode 20 can include materials capable of carrying electric current and providing charge to the semiconducting ferroelectric layer 16. In some embodiments, metals can be used. Metals can include pure metals, metal alloys, or layered metals. In some embodiments titanium, aluminum, or titanium/aluminum alloys can be used. In some embodiments, doped or undoped polycrystalline silicon can be the top electrode.

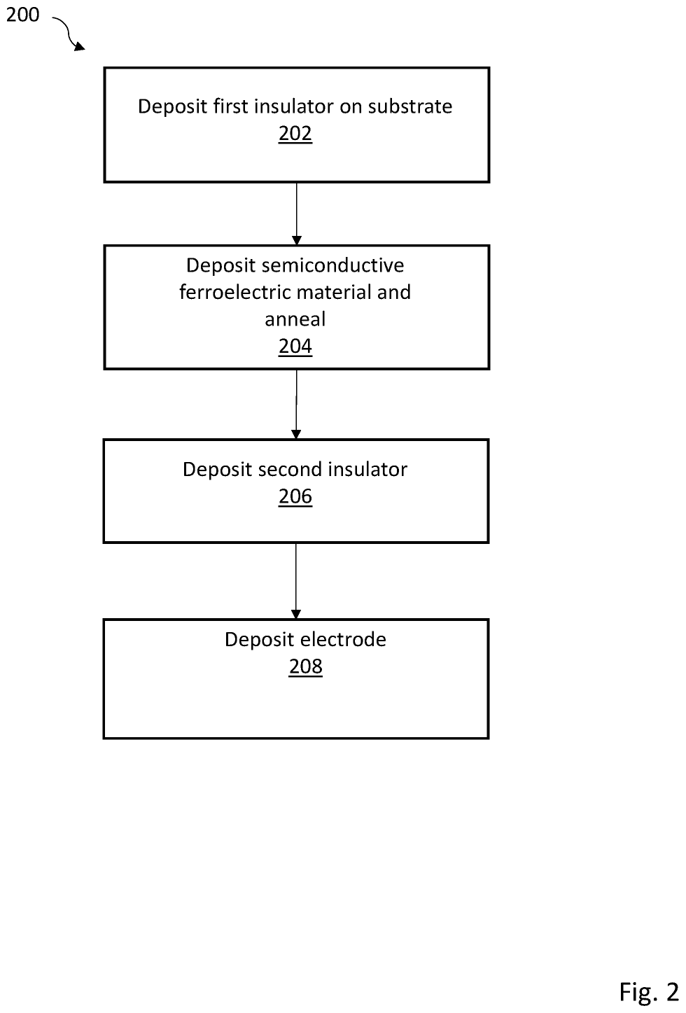

FIG. 2 shows a schematic representation of a process embodiment for manufacture of device stack such as illustrated with respect to FIG. 1. In this embodiment a substrate is provided to support deposit of a first insulator layer (step 202). Deposition can be directly on the substrate or can be on one or more buffer layers selected to improve layer adhesion, provide lattice matching, or allow for deposition of disparate material. In some embodiments, the first insulator layer can include multiple layers that are compositionally or structurally distinct. Next, after optional deposition of buffer layer(s), conducting layers that can include metals, metalloids, or conductive oxides, or stress layer(s), a semiconducting ferroelectric layers is deposited and annealed at a temperature below 450 degrees Celsius (step 204). Annealing can be immediate, or after further deposition of additional materials. Additional materials can include optional deposition of buffer layer(s), conducting layers that can include metals, metalloids, or conductive oxides, or stress layer(s). A second layer of insulating material can be deposited onto or above the semiconducting ferroelectric layer (step 206). An electrode can be deposited onto or above the second layer of insulating material.

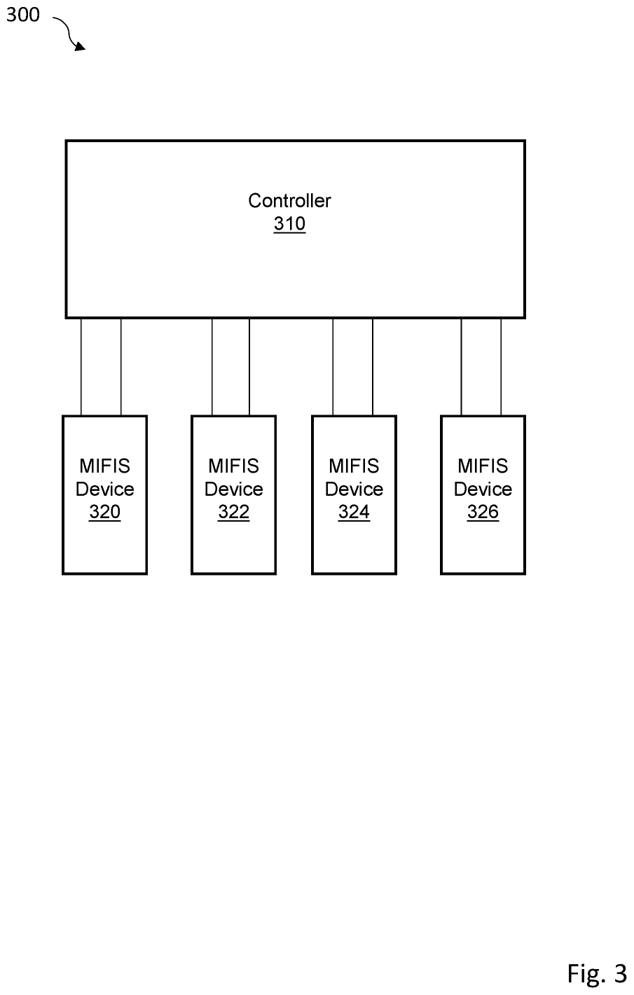

FIG. 3 shows a schematic representation of a system including a controller 310 for a plurality of MIFIS devices 320, 322, 324, and 326. Each MIFIS device includes one or more polarization modifiable device stacks such as disclosed herein. In this embodiment, the MIFIS devices 320, 322, 324, and 326 include a substrate supporting first and second layers of insulating material, with the first layer of insulating material supported by the substrate. A semiconducting ferroelectric layer that is positioned and electrically isolated between the first and second layers of insulating material, which also have an electrode positioned onto or above the second layer of insulating material. The controller 310 can be operated to read or change polarization state of the semiconducting ferroelectric layer using the electrode.

Having described the general details of embodiments of the present invention, the following examples provide additional details.

### Example 1

In one embodiment, a device such as disclosed with respect to FIG. 1 includes a polarizable ferroelectric semiconducting material that includes Bi₄Ti₃O₁₂ doped with less than 15% by atomic mass of BiₓO_{y}, where 1≤x≤2, and 1≤y≤3 (BiO or Bi₂O₃).

### Example 2

Thin films (≤30 nm) of doped or undoped Bi₄Ti₃O₁₂ were prepared by atomic layer deposition on a 5 nm film of HfO₂ and covered with a 5 nm film of HfO₂ before a step of rapid thermal annealing at 450 C for 1 min. under nitrogen.

The foregoing description of the invention has been presented for purposes of illustration and description and is not intended to be exhaustive or to limit the invention to the precise form disclosed, and obviously many modifications and variations are possible in light of the above teaching. The embodiments were chosen and described in order to best explain the principles of the invention and its practical application to thereby enable others skilled in the art to best utilize the invention in various embodiments and with various modifications as are suited to the particular use contemplated

1. A device stack, comprising:
a substrate;
first and second layers of insulating material, with the first layer of insulating material supported by the substrate;
a semiconducting ferroelectric layer that is positioned and electrically isolated between the first and second layers of insulating material; and
an electrode formed from a semiconducting material positioned onto or above the second layer of insulating material.

2. The device stack of claim 1, wherein the semiconducting material forming the electrode is doped.

3. The device stack of claim 1, wherein the semiconducting material forming the electrode is at least one of crystal silicon, crystal germanium, silicon carbide, doped and/or undoped semiconductors, Group IV elemental semiconductors, (C, Si, Ge, Sn), Group IV compound semiconductors, Group VI elemental semiconductors, (S, Se, Te), III-V semiconductors, II-VI semiconductors, I-VII semiconductors, IV-VI semiconductors, V-VI semiconductors, II-V semiconductors, I-III-VI2 semiconductors, semiconducting oxides, or layered semiconductors.

4. The device stack of claim 1, wherein the substrate is a semiconducting substrate.

5. The device stack of claim 1, wherein the semiconducting ferroelectric layer has at least one substituent or a Bi, Nb, La, Ta, Zr, Dy, Sm, Cr, Sb, Fe, Si, Al, Pb, Hf, Ba, or Cd with at least an amount greater than 1 At %.

6. The device stack of claim 1, wherein the semiconducting ferroelectric layer is doped with at most 1 At % of one of Dy, Sm, Sc, Cr, Sb, Fe, Si, Al, Ga, Ge, Hf, Ba, or Y.

7. A method for forming a device stack, comprising:
providing a substrate;
depositing a first layer of insulating material onto or above the substrate;
depositing at least one of a material layer onto or above the first layer of insulating material;
providing stress to convert the material layer into a semiconducting ferroelectric layer; and
depositing a second layer of insulating material onto or above the semiconducting ferroelectric layer.

8. The method for forming a device stack of claim 7, wherein the material layer is ferroelectric.

9. The method for forming a device stack of claim 7, wherein the material layer is semiconductive.

10. The method for forming a device stack of claim 7, wherein the stress is created by external stress applied by an external structure.

11. The method for forming a device stack of claim 7, wherein the external structure is a stress layer formed in contact with the material layer.

12. The method for forming a device stack of claim 7, wherein the external structure is a stress layer comprising at least one of a buffer layer, an insulator layer, a semiconducting layer, or a conducting oxide layer.

13. The method for forming a device stack of claim 7, wherein the external structure is a stress layer comprising a semiconducting layer further comprising a silicon germanium layer formed in contact with the material layer.

14. The method for forming a device stack of claim 7, wherein the stress is created by an internal stress.

15. The method for forming a device stack of claim 7, wherein the stress is created by an internal stress applied by at least one of crystallographic structural changes imparted to the material, by alloying the material layer, or by doping the material layer.

16. A device stack, comprising:
a substrate;
first and second layers of insulating material, with the first layer of insulating material supported by the substrate;
a semiconducting ferroelectric layer that is positioned and electrically isolated between the first and second layers of insulating material; and
a conductive layer positioned at least one of below and above the semiconducting ferroelectric layer.

17. The device stack of claim 16, wherein the conductive layer comprises a first conductive layer positioned between the semiconducting ferroelectric layer and first layer of insulating material.

18. The device stack of claim 16, wherein the conductive layer comprises a second conductive layer positioned between the semiconducting ferroelectric layer and second layer of insulating material.

19. The device stack of claim 16, wherein the conductive layer comprises at least one a metal, a metalloid, or a conductive oxide.

20. The device stack of claim 16, wherein the conductive layer comprises a non-dielectric oxide, including at least one of a doped conductive oxide, conductive metal oxide, doped conductive metal oxide, semiconductive oxide, or semiconductive metal oxide.

21. The device stack of claim 16, wherein the conductive layer comprises a conductive perovskite oxide, a high temperature superconducting oxide, or an oxide film of any metal selected from a group consisted of Mo, W, Tc, Re, Ru, Os, Rh, Ir, Pd, Pt, In, Zn, Sn, Nd, Nb, Sm, La, and V

22. The device stack of claim 16, wherein the conductive layer includes a conductive oxide that comprises at least one of indium oxide, indium tin oxide, ruthenium oxide, iridium oxide, tungsten oxide, molybdenum oxide, titanium oxide, iron oxide, tin oxide, zinc oxide, CeO₂, Ga₂O₃, SrTiO₃, LaFeO₃, or CrₓTi_{y}O₃.

23. The device stack of claim 16, wherein the semiconducting ferroelectric layer has spontaneous polarization.

24. The device stack of claim 16, comprising an electrode positioned onto or above the second layer of insulating material.

25. The device stack of claim 16, wherein the substrate is a semiconducting substrate.

26. A method for forming a device stack, comprising:
providing a substrate;
depositing a first layer of insulating material onto or above the substrate;
depositing a semiconducting ferroelectric layer onto or above the first layer of insulating material;
depositing a second layer of insulating material onto or above the semiconducting ferroelectric layer; and wherein
at least one conductive layer is deposited at least one of below and above the semiconducting ferroelectric layer.

27. A method for forming a device stack, comprising:
providing a substrate;
depositing a first layer of insulating material onto or above the substrate;
depositing a semiconducting ferroelectric layer onto or above the first layer of insulating material;
depositing a second layer of insulating material onto or above the semiconducting ferroelectric layer; and
positioning an electrode formed from a semiconducting material onto or above the second layer of insulating material.

28. A method of operating a device stack, comprising:
providing a substrate supporting first and second layers of insulating material, with the first layer of insulating material supported by the substrate, and wherein a semiconducting ferroelectric layer that is positioned and electrically isolated between the first and second layers of insulating material, further having an electrode formed from a semiconducting material and positioned onto or above the second layer of insulating material; and
operating a controller to apply an electric field via the electrode formed from the semiconducting material to modify polarization state of the semiconducting ferroelectric layer.
